(19) United States
(12) Patent Application Publication
(10) Pub. No.: US 2011/0237011 A1
(43) Pub. Date: Sep. 29, 2011

(54) Method for Forming a GaN-Based Quantum-Well LED with Red Light

(75) Inventors: RONG ZHANG, Nanjing (CN); ZILI XIE, Nanjing (CN); BIN LIU, Nanjing (CN); MING LI, Nanjing (CN); XIANGQIAN XIU, Nanjing (CN); DEYI FU, Nanjing (CN); XUEMEI HUA, Nanjing (CN); HONG ZHAO, Nanjing (CN); PENG CHEN, Nanjing (CN); PING HAN, Nanjing (CN); YOUDOU ZHENG, Nanjing (CN)

(73) Assignee: NANJING UNIVERSITY, Nanjing (CN)

(21) Appl. No.: 12/748,462

(22) Filed: Mar. 29, 2010

(51) Int. Cl. H01L 21/20

(52) U.S. Cl. 438/47; 257/E21.09

(57) ABSTRACT

This invention presents a growth method for GaN based quantum wells red light LED structure by MOCVD epitaxy growth system, GaN based GaN/InGaN quantum wells red light LED structure material is obtained. The In mole fraction (x) for quantum well material InGaN is controlled between 0.1 and 0.5. This invention realizes the lumiscience of long wave length red light in group III nitrides. Aiming at the problem of difficulty in growing high In composition InGaN material, this invention solves this problem by controlling and adjusting the flux of organic Ga source and In source, growth temperature, time, and the flux of ammonia, and the mole ratio of N to Ga. By strictly controlling the conditions such as temperature and the flux ratio of reactant in the whole process, this invention determines the radiation wave length of quantum well, realizes the lumiscience of long wave length, and obtained GaN based GaN/InGaN quantum well red light LED structure.

### FIELD OF THE INVENTION

This invention deals with a new growth method for GaN based GaN/InGaN quantum wells red light LED structure materials, especially the growth method for GaN based GaN/InGaN quantum wells red light LED structure upon sapphire substrate by MOCVD technique.

### BACKGROUND OF THE INVENTION

Since Nakamura et al. in Nichia Company made out GaN based blue light LED successfully in 1991, the research in group III nitrides semiconductor materials and devices have developed rapidly. Short wave length LED and laser devices with high efficiency have been made out. InGaN based multiple MQWs structure are the core structure of all these devices. To study and master deeply the optoelectric properties of InGaN based MQWs is of great importance. In InGaN based multiple MQWs, the localization of carriers has been widely studied, generally the behavior of carriers is thought to be constrained within a narrow range to combine radioactively, and not been captured by defects, this is the important reason for high efficiency of short wave light emission.

The physical pictures and laws of the localization of carriers in nitrides are controversial at present. Many models and descriptions have been proposed, and most of them mainly concentrate on the following three models: (1) the fluctuation of monolayer thickness in heterojunctions leads to kinds of quantum wells with different practical thickness in the whole structure, and different quantum wells have different confinement effect on carriers; (2) the no uniform distribution of the composition and stress in space leads to the fluctuation of potential well in the whole structure; (3) the total phase separation leads to quantum wells with different composition include in the whole structure.

The common character of all the models is that the localization effect embodies in the fluctuation of one parameter, such as the fluctuation of thickness or composition. Moreover, by the observation with TEM, for a long time this fluctuation is thought to lead to the formation of quasi quantum dots structure. The research results in recent two years show that the result of TEM is not the reason for the generation of localization, at present there are no observed results for physical structure of localization. The localization of carriers embodies is very eminently in the optoelectronic behavior, but its physical structure and energy structure have not been known clearly. The ambiguity of the intrinsic laws leads to that apparent measurement and summary of laws to explore are main ways to design structures and study devices for Group III nitrides.

Among the deep research on the localization of carriers in nitrides, a new assumption is that a small atomic level physical microstructure leads to the localization of carriers. So general measurement methods, such as TEM, can not observe this effect. Such atomic scale localization model corresponds to our earlier experimental results. We observed the change of light emission led by changes of atomic scale structure in special designed nitrides.

A preliminary validation of the guess is the positron fluorescence experiment in nitrides semiconductors done by Japanese scientist Chi Chi Bu's group. The results show the unknown behavior of holes: the diffuse length is within only several lattice constant, smaller than 4 nm, greatly different from several decades and one hundred nm deemed before. The utterly new carrier behavior disclosed here provide warrant and foundation for designing more accurate energy band structure for nitrides, and utilizing sufficiently the material properties of nitrides to realize radioactive combination with high efficiency to design new quantum structures in nitrides materials with high density of background defects.

Many behaviors of carriers are confined in extreme narrow space, even the material of epilayer has very high density of defects, the effect of these defects was suppressed for the behavior of carriers was localized. This the basic reason for the realization of high efficiency light emission in blue-green light emitting devices although nitrides materials have high density of defects. To study thoroughly the essential reason and practical physical structure for carriers localization is of great importance to know deeply the properties of nitrides semiconductor materials, and we can further utilize purposefully and sufficiently this eminent property of nitrides semiconductors to expolore and practice nitrides quantum structures and devices with new property.

Realization of red-light-emitting system with nitrides semiconductors is always the hot topic in the frontier of research in nitrides. The high efficiency light emission of special wave length for general blue-green-light-emitting devices can be realized by utilizing nitrides multiple quantum well structure. This is decided by the quantum structure properties of active region in devices. Because of the difficulty in growing high In composition InGaN material, the structure materials for realization of red light emission GaN based LED have not been reported.

### SUMMARY OF THE INVENTION

The problem to solve in this invention is: now there is no report about the structure material for realization of red light emission GaN based LED, and the need of a new growth method for GaN based GaN/InGaN quantum wells red light LED structure materials, especially the growth method for GaN based GaN/InGaN quantum wells red light LED structure upon sapphire substrate by MOCVD technique.

The technical programe for this invention: A method for forming a GaN-based quantum-well LED with red light, comprising: using MOCVD growth system,

1) heat the sapphire substrate at a temperature between 1000° C. and 1100° C., then feed ammonium to make surface-nitriding, or feed a metal organic source of Al to grow a 2-20 nm-thick AlN layer on Si substrate at a temperature between 1000° C. and 1100° C.;

2) feed carrier gas N₂, ammonia and metal organic source into the MOCVD growth system at a temperature between 500° C. and 700° C., to grow a low temperature GaN buffer layer on the substrate said in step 1), wherein said metal organic source is Ga source;

3) grow at a temperature between 1000° C. and 1150° C. more than 10 minutes to obtain a GaN sustaining layer which has a thickness more than 50 nm;

4) after the growth of GaN sustaining layer, feed SiH₄ into the MOCVD growth system at a temperature between 900° C. and 1050° C. to grow a layer of Si-doped N type GaN; then feed Ga source and In source to grow 2-10 periods GaN/InGaN multiple-quantum-well structure which has a thickness GaN between 15 nm and 20 nm at a growth temperature between 700° C. and 900° C., and a thickness InGaN between 5 nm and 15 nm at a growth temperature between 600° C. and 850° C., wherein said Ga source is TMGa and In source is TMIn, the mole fraction x of InₓGa₁₋ₓN of the multiple-quantum-well structure is controlled between 0.1 and 0.5 by temperature or the flux of TMIn, to ensure the wave length of light is between a range of 550 nm and 780 nm which performed as red;

5) by growing P type GaN layer with Mg doping concentration reaching to 3×10¹⁷ cm⁻³ to make LED device structure, and activate by annealing for 0.1-1 hour at a temperature between 600° C. and 800° C. to obtain GaN-based GaN/InGaN quantum-well LED with red light grown upon sapphire or Si substrate.

Wherein said Ga source is TMGa and with the flux between 1-50 sccm, wherein said In source is TMIn and with the flux between 50-200 sccm, the MOCVD system's growth temperature is between 500° C. and 1050° C., growth time is between 5 to 3600 seconds, the flux of the ammonia is controlled within 500 to 700 sccm, and V/III ratio is 500 to 50000, wherein said V/III ratio is the mole ratio of N to Ga.

The In mole fraction (x) in quantum well material InₓGa₁₋ₓN for red light LED structures obtained by the above method was controlled between 0.1 and 0.5 by the temperature or the flux of Trimethylindium (TMIn), to ensure the wave length of light is red, eq. in the range between 550 nm and 780 nm.

2-10 periods GaN/InGaN multiple quantum well structures of 15-20 nm-thick and 5-15 nm-thick, respectively, and the in mole fraction (x) for quantum well material InₓGa₁₋ₓN was controlled between 0.1 and 0.5 by the temperature or the flux of Trimethylindium (TMIn). This is crucial for this invention.

This invention realizes the lumiscience of long wave length red light in group III nitrides. Aiming at the problem of difficulty in growing high In composition InGaN material, this invention solve this problem by controlling and adjusting the flux of organic Ga source and In source, growth temperature, time, and the flux of ammonia, and the ratio of N to Ga. By strictly controlling the conditions such as temperature and the flux ratio of reactant in the whole process, this invention determine the light wave length of quantum well, realized the lumiscience of long wave length, and obtained GaN based GaN/InGaN quantum well red light LED structure.

### BRIEF DESCRIPTION OF THE DRAWINGS

FIG. 1 is the three dimension AFM micrograph of InGaN/GaN multiple quantum well red light LED structure grown in this invention.

FIG. 2 are spectra of triple-axis X-ray diffraction and fitting figure of (002) plane for GaN based GaN/InGaN multiple quantum well red light LED structure grown in this invention.

FIG. 3 is the room temperature PL spectra of red light LED structure grown in this invention.

FIG. 4 is the red light photograph of PL for this LED structure.

### DETAIL DESCRIPTION OF THE INVENTION

This invention grows GaN based GaN/InGaN quantum well red light LED structure by making use of MOCVD epitaxy growth system, including the following detailed steps:

1) After the heat treatment of the sapphire substrate under 1000-1100° C., the ammonia gas was fed into the reactor to get nitridated surface, or the organic Al source was fed into the reactor to grow a 2-20 nm-thick AlN layer under 1000-1100° C.;

2) Carrier gas N₂, ammonia and metallic organic Ga source were fed into the reactor under the temperature range of 500-700° C. to grow and synthesize low temperature GaN buffer upon the substrate pretreated in process 1);

3) More than 50 nm-thick GaN sustaining layer can be obtained by growing the sample under the temperature of 1000-1150° C. for more than 10 minutes. The longer growth time, the thicker the sustaining layer, so we can choose growth time and thickness according to needs.

4) After the growth of sustaining layer material, the SiH₄ was fed into the reactor to grow a layer of Si doped N type GaN; then organic Ga source Trimethylgallium (TMGa) and organic In source Trimethylindium (TMIn) were fed into the reactor at the same time to grow 2-10 periods GaN/InGaN multiple quantum well structures of 15-20 nm-thick under 700-900° C. and 5-15 nm-thick under 600-800° C. the In mole fraction (x) for quantum well material InₓGa₁₋ₓN is controlled between 0.1 and 0.5 by temperature or the flux of Trimethylindium (TMIn), to ensure the wave length of light is red, eq. in the range between 550 nm and 780 nm.

The organic Ga source and In source are Trimethylgallium (TMGa) and Trimethylindium (TMIn) in MOCVD system with the flux equal to 1-50 sccm and 50-200 sccm, respectivly, under 500-1050° C. for 5-3600 seconds. The flux of the ammonia was controlled within 500-700 sccm, and V/III ratio (the mole ratio of N to Ga) is 500-50000.

5) By growing P type GaN layer with Mg doping concentration reaching to 3×10¹⁷ cm⁻³ to make LED device structure, and activating by annealing for 0.1-1 hour under 600-800° C. we obtain GaN based GaN/InGaN quantum well red light LED structure material upon sapphire or Si substrate.

Finally, by growing P type GaN layer with Mg doping concentration reaching to 3×10¹⁷ cm⁻³ to make LED device structure, and activating by anneal for 0.1-1 hour under 600-800° C. we get GaN/InGaN quantum well LED device structure.

FIG. 1 is the three dimension AFM micrograph of red light LED structures based on InGaN/GaN quantum wells. We can see from the figure that there are a lot of island protuberances, among which the highest is 30.564 nm, and the average roughness is 5.68 nm. The relaxation crical thickness calculated by W. Lu et al. is 4.8148 nm for InGaN well layer with In composition being 17.695%. But this invention get the well thickness is 4.855 nm by fitting, which is a bit bigger than the critical thickness, and has relaxed in strain, which shows the quality of the material in this invention is pretty good.

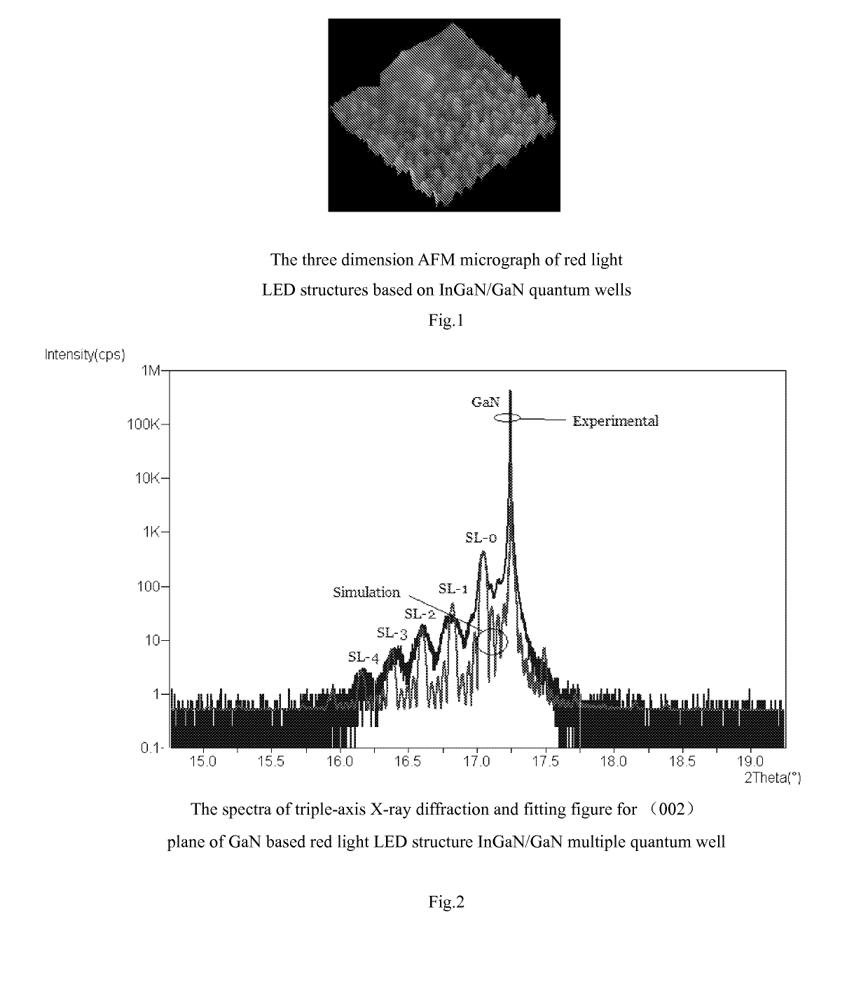

FIG. 2 is the spectra of triple-axis X-ray diffraction and fitting figure for (002) plane of GaN based red light LED structure InGaN/GaN multiple quantum well sample grown in this invention. We can see that, the position of the peak for (002) plane is lie in 17.2465°. Its right satellite peak arrived at minus four level, which shows the good quality of interface of InGaN/GaN sample. The fitting results show the well thickness is 4.855 nm and in composition is 17.695%, the barrier thickness is 15.985 nm and in composition is 4.162%.

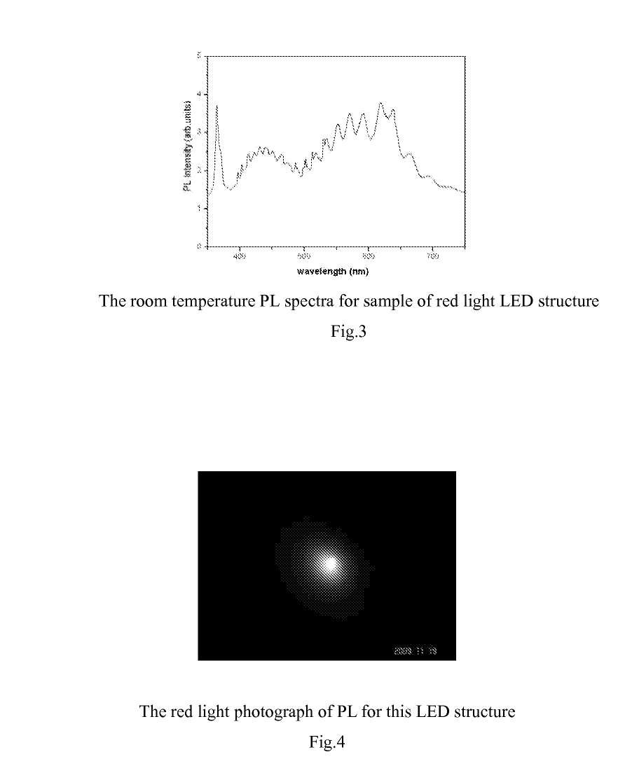

FIG. 3 is the room temperature PL spectra for sample of red light LED structure grown in this invention. We can see clearly that the double emission peaks of InGaN quantum well. The positions of them locate at 434 nm and 579 nm, respectively. The leftmost peak located at 364 nm is photolumiscience of GaN layer. The surface in figure has an acute peak, this structure can increase the complete segregation of in ingredient in well layer of InGaN multiple quantum well. The In rich region formed by segregation can form quantum wire and quantum dot structure at the surface. There are reports about studying the origin of double peaks in electrolumiscience of InGaN/GaN multiple quantum well, thinking that the emission of long wave length light originates from lumisience of quantum well and quantum dot and the short wave length light originates from lumisience of InGaN quantum well. So we deduce that the peak wave length at 579 nm is generated by the photolumiscience of quantum dot at surface, while the peak 434 nm corresponds to the InGaN well layer under the surface of sample. Whereas the penetration depth is limited, the intensity of short wave length light generated by well layer far from the surface is relatively weak. Most of the excited light is absorbed by the surface, and then we get the desired long wave length light. FIG. 4 is the red light photograph of PL for this LED structure. So we can observe evident emission of red light in photolumiscience experiments.

This invention presents a method to grow GaN based quantum wells red light LED structure upon sapphire substrate making use of MOCVD epitaxy growth system. No reports about making use of high in composition InGaN/GaN quantum wells to design red light LED have been seen. This invention first make use of MOCVD growth method to synthesize GaN based red light LED structure, it is the first time in technique.

MOCVD technology is a common method for material growth, but it is worthwhile studying how to choose the substrate and how to obtain high crystallized and high quality InGaN/GaN quantum material, including the problems of technical conditions for growth and the design of buffer, and so on, and both of them are problems need to be solved in production. This invention is an innovation in material, an improvement in growth method, and has further extensive practical applications.

1. A method for forming a GaN-based quantum-well LED with red light consisting of a sapphire substrate, a AlN layer, a GaN buffer layer, a GaN sustaining layer and a GaN/InGaN multi-quantum-well layer comprising:
1) using a MOCVD growth system, put a sapphire substrate in a MOCVD growth system;
2) heat the sapphire substrate at a temperature between 1000° C. and 1100° C., then feed ammonium to make surface-nitriding, or feed a metal organic source of Al to grow a 2-20 nm-thick AlN layer on Si substrate at a temperature between 1000° C. and 1100° C.;
3) feed carrier gas N₂, ammonia and metal organic source into the MOCVD growth system at a temperature between 500° C. and 700° C. to grow a low temperature GaN buffer layer on the substrate said in step 2), said metal organic source is Ga source;
4) grow at a temperature between 1000° C. and 1150° C. more than 10 minutes to obtain a GaN sustaining layer which has a thickness more than 50 nm;
5) after the growth of GaN sustaining layer, feed SiH₄ into the MOCVD growth system at a temperature between 900° C. and 1050° C. to grow a layer of Si-doped N type GaN; then feed Ga source and In source to grow 2-10 periods GaN/InGaN multiple-quantum-well structure which has a thickness GaN between 15 nm and 20 nm at a growth temperature between 700° C. and 900° C., and a thickness InGaN between 5 nm and 15 nm at a growth temperature between 600° C. and 800° C., wherein said Ga source is TMGa and In source is TMIn, a mole fraction x of InₓGa₁₋ₓN of the multiple-quantum-well structure is controlled between 0.1 and 0.5 by temperature or flux of the TMIn, to ensure a wave length of light is between a range of 550 nm and 780 nm which performed as red;
6) by growing P type GaN layer with Mg doping concentration reaching to 3×10¹⁷ cm⁻³ to make LED device structure, and activate by annealing for 0.1-1 hour at a temperature between 600° C. and 800° C. to obtain the GaN-based GaN/InGaN quantum-well LED with red light grown upon sapphire or Si substrate.

2. The method according to claim 1, wherein said Ga source is TMGa and with the flux between 1-50 sccm, said In source is TMIn and with the flux between 50-200 sccm, the MOCVD system's growth temperature is between 500° C. and 1050° C., growth time is between 5 to 3600 seconds, the flux of the ammonia is controlled within 500 to 700 sccm, and V/III ratio is 500 to 50000, said V/III ratio is the mole ratio of N to Ga.
